(19) United States
(12) Patent Application Publication
(10) Pub. No.: US 2024/0405164 A1
(43) Pub. Date: Dec. 5, 2024

(54) ELECTRONIC DEVICE AND METHOD OF PROVIDING THE SAME

(71) Applicant: Samsung Display Co., Ltd., Yongin-si (KR)

(72) Inventors: YOUNGDO KIM, Yongin-si (KR); BYUNGHOON KIM, Yongin-si (KR); JEONGWEON SEO, Yongin-si (KR); JUNWOO YOU, Yongin-si (KR); JUNYOUNG LEE, Yongin-si (KR); CHANGMOO LEE, Yongin-si (KR); SUK WON JUNG, Yongin-si (KR)

(21) Appl. No.: 18/596,862

(22) Filed: Mar. 6, 2024

(30) Foreign Application Priority Data
May 31, 2023 (KR) 10-2023-0070368

(51) Int. Cl. H01L 33/44; H01L 25/075

(52) U.S. Cl. CPC H01L 33/44; H01L 25/0753; H01L 2933/0025

(57) ABSTRACT

An electronic device includes a display panel including a first region corresponding to an electronic module, a second region which extends from the first region, and a third region which is spaced apart from the first region with the second region therebetween, and a protective layer facing the display panel at the second region and the third region. The protective layer includes a first protective part including an ultraviolet curable resin, the first protective part being adjacent to the first region and overlapping the second region, and a second protective part including a heat radiating material, the second protective part being adjacent to the second region and overlapping the third region.

This application claims priority to Korean Patent Application No. 10-2023-0070368 filed on May 31, 2023, and all the benefits accruing therefrom under 35 U.S.C. § 119, the disclosures of which are incorporated by reference herein in their entireties.

### BACKGROUND

### (1) Field

Embodiments of the present disclosure described herein relate to an electronic device and a method or manufacturing thereof. More particularly, one or more embodiment relates to an electronic device with improved reliability and a method of manufacturing (or providing) the same.

### (2) Description of the Related Art

An electronic device including a display device, such as a smart phone, a digital camera, a notebook computer, a car navigation unit, a smart television, or the like, provides an image to a user through a display screen.

The display device may include a display panel that provides image information and a protective layer for protecting the display panel from the outside. The protective layer protects the display panel from the outside by preventing deformation of the display panel by an external impact and effectively releasing heat generated from the display panel. In order to provide various functions for protecting the display panel, the protective layer has a structure in which multiple functional layers are stacked one above another.

### SUMMARY

A multilayer protective layer having multiple functional layers may increase an overall thickness of the electronic device or may complicate a method of providing the electronic device. An electronic device including a single protective layer which protects a display panel of the electronic devices and integrally has various functions has been studied.

Embodiments of the present disclosure provide an electronic device with improved reliability and a method of manufacturing (or providing) thereof.

According to an embodiment, an electronic device includes a display panel including a first region, a second region which surrounds at least a portion of the first region, and a third region, at least a portion of which is spaced apart from the first region with the second region therebetween, an electronic module which overlaps the first region and which is under the display panel, and a protective layer which overlaps the second region and the third region and which is under the display panel. The protective layer includes a first protective part which overlaps the second region and includes an ultraviolet curable resin and a second protective part which overlaps the third region and includes a heat radiating material.

At least one of the first protective part and the second protective part may further include a light blocking material.

The first protective part may include a light blocking material including an ultraviolet transmitting material.

At least one of the first protective part and the second protective part may further include a foaming agent.

The second protective part may further include a thermosetting resin, a light blocking material, a foaming agent, and an additive.

The protective layer may have a hole defined therein to overlap the first region, and the first protective part may surround the hole.

The protective layer may be directly on a lower surface of the display panel.

A thickness of the first protective part and a thickness of the second protective part may range from about 50 micrometers (μm) to about 300 μm.

The first protective part may have substantially the same thickness as the second protective part.

The first protective part and the second protective part may not overlap each other on a plane.

The electronic device may further include a filling layer which overlaps the first region and transmits light.

The heat radiating material may have an average diameter of about 5 μm to 100 μm.

The display panel may include an active region including the first region, the second region and the third region, and a peripheral region which surrounds the active region, and the protective layer may overlap at least a portion of the peripheral region.

The protective layer may further include a third protective part which overlaps the peripheral region and includes an ultraviolet curable resin.

According to an embodiment, an electronic device includes a display panel including a first region, a second region adjacent to at least the first region, and a third region adjacent to the second region, an electronic module which overlaps the first region and which is under the display panel, and a protective layer which overlaps the second region and the third region and which is under the display panel. The protective layer includes a first protective part which overlaps the second region and a second protective part which overlaps the third region. The first protective part includes a first base resin including an ultraviolet curable resin, and the second protective part includes a second base resin different from the first base resin and a heat radiating material dispersed in the second base resin.

According to an embodiment, a method for manufacturing (or providing) an electronic device includes providing a display panel including a first region, a second region adjacent to the first region, and a third region spaced apart from the first region with the second region therebetween, providing a first protective part by providing a first resin to a lower surface of the display panel such which the first resin overlaps the second region, providing a second protective part by providing a second resin to the lower surface of the display panel such which the second resin overlaps the third region, and providing an electronic module such which the electronic module overlaps the first region. The first resin includes an ultraviolet curable resin, and the second resin includes a heat radiating material.

The providing of the first protective part may include applying the first resin to the lower surface of the display panel and curing the first resin using ultraviolet light.

The providing of the second protective part may include applying the second resin to the lower surface of the display panel and curing the second resin using heat.

The second resin may further include a thermosetting resin, a light blocking material, a foaming agent, and an additive.

The display panel may include an active region including the first region, the second region and the third region, and a peripheral region which surrounds the active region. The method may further include providing a third protective part by providing a third resin to the lower surface of the display panel such which the third resin overlaps the peripheral region, before the forming of the second protective part. The third resin may include an ultraviolet curable resin.

### BRIEF DESCRIPTION OF THE FIGURES

The above and other objects and features of the present disclosure will become apparent by describing in detail embodiments thereof with reference to the accompanying drawings.

FIG. 1 is a perspective view of an electronic device according to an embodiment of the present disclosure.

FIG. 2 is an exploded perspective view of the electronic device according to an embodiment of the present disclosure.

FIG. 3 is a cross-sectional view illustrating some components of the electronic device according to an embodiment of the present disclosure.

FIG. 4 is a cross-sectional view of a display panel according to an embodiment of the present disclosure.

FIG. 5A is a plan view of a protective layer according to an embodiment of the present disclosure.

FIGS. 5B and 5C are cross-sectional views of portions of the electronic device according to embodiments of the present disclosure.

FIGS. 6A and 6B are enlarged cross-sectional views of portions of the electronic device according to embodiments of the present disclosure.

FIG. 7 is a cross-sectional view of a portion of the electronic device according to an embodiment of the present disclosure.

FIG. 8 is a flowchart illustrating a method of providing the electronic device according to an embodiment of the present disclosure.

FIGS. 9A to 9E are cross-sectional views illustrating the method of providing the electronic device according to an embodiment of the present disclosure.

FIGS. 10A to 10E are cross-sectional views illustrating the method of providing the electronic device according to an embodiment of the present disclosure.

### DETAILED DESCRIPTION

In this specification, when it is mentioned that a component (or, an area, a layer, a part, etc.) is referred to as being related to another element such as being “on”, “connected to” or “coupled to” another component, this means that the component may be directly on, connected to, or coupled to the other component or a third component may be present therebetween. In contrast, when a component (or, an area, a layer, a part, etc.) is referred to as being related to another element such as being “directly on”, “directly connected to” or “directly coupled to” another component, this means that no third component is present therebetween.

The expression “directly disposed” used herein may mean that there is no additional layer, film, area, or plate between one portion, such as a layer, a film, an area, or a plate, and another portion. For example, the expression “directly disposed” may mean that two layers or two members are disposed without an additional member such as an adhesive member therebetween. Elements that are ‘directly’ disposed relative to each other, may form an interface therebetween.

The invention is described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout. Identical reference numerals refer to identical components. Additionally, in the drawings, the thicknesses, proportions, and dimensions of components are exaggerated for effective description. Within the Figures and the text of the disclosure, a reference number indicating a singular form of an element may also be used to reference a plurality of the singular element.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component.

The terms of a singular form may include plural forms unless otherwise specified. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes all of one or more combinations defined by related components.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the accompanying drawings.

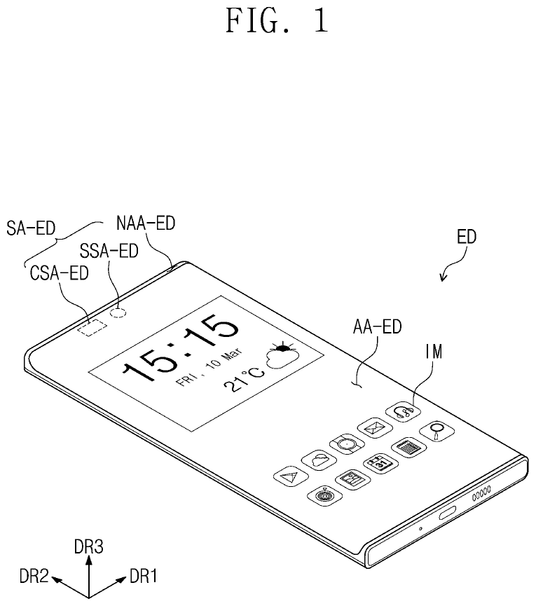

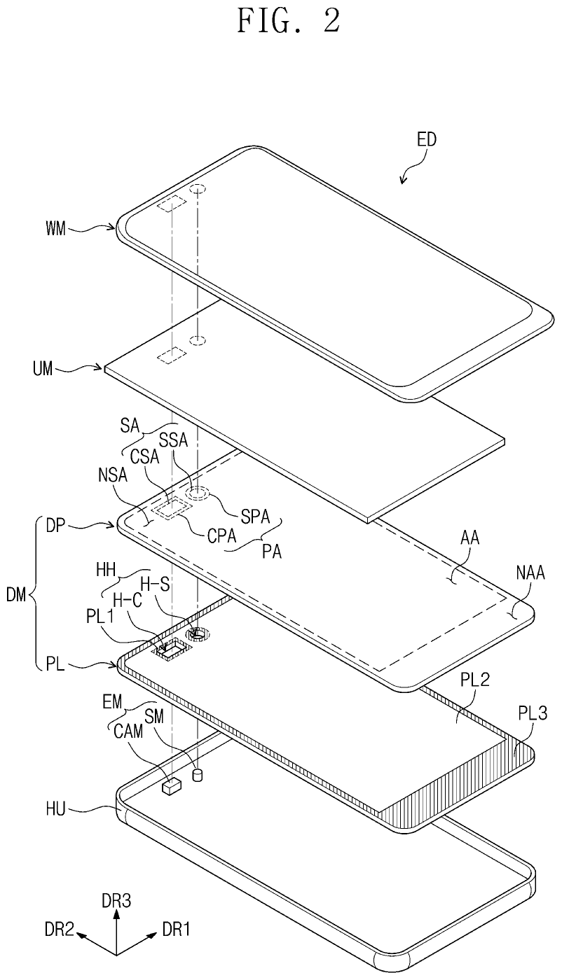

FIG. 1 is a perspective view of an electronic device ED according to an embodiment of the present disclosure. FIG. 2 is an exploded perspective view of the electronic device ED according to an embodiment of the present disclosure.

The electronic device ED of one embodiment may be a device activated depending on an electrical signal. For example, the electronic device ED may be a mobile phone, a tablet computer, a car navigation unit, a game machine, or a wearable device, but is not limited thereto. FIG. 1 illustrates an example that the electronic device ED is a mobile phone.

The electronic device ED may display an image IM through an active region AA-ED. The active region AA-ED may include a flat surface defined by or parallel to a plane defined by a first direction DR1 and a second direction DR2 which cross each other. The active region AA-ED may further include a curved surface which is bent from at least one side of the flat surface defined by the first direction DR1 and the second direction DR2. The electronic device ED of the embodiment illustrated in FIG. 1 is illustrated as including two curved surfaces bent along the second direction DR2 from opposite sides of the flat surface defined by the first direction DR1 and the second direction DR2. However, the shape of the active region AA-ED is not limited thereto. For example, the active region AA-ED may include only the flat surface. Alternatively, the active region AA-ED may further include four curved surfaces bent from at least two sides, for example, four sides of the flat surface, in various directions away from the flat surface.

Although the first to third directions DR1 to DR3 are illustrated in FIG. 1 and the following drawings, the directions indicated by the first direction DR1, the second direction DR2, and the third direction DR3 described in this specification may be relative concepts and may be changed to different directions.

In this specification, the first direction DR1 and the second direction DR2 may be orthogonal to each other, and the third direction DR3 may be a normal direction to the flat surface defined by the first direction DR1 and the second direction DR2. The expression “from above a plane” used herein may mean that it is viewed from above the plane defined by the first direction DR1 and the second direction DR2. A thickness direction may refer to the third direction DR3 that is a normal direction to the plane defined by the first direction DR1 and the second direction DR2 crossing each other.

A sensing region SA-ED may be defined in the electronic device ED. The sensing region SA-ED may correspond to a location where a functional component of the electronic device ED is disposed. The functional component may provide a function to the electronic device ED, such as by using light, sound, pressure, etc. Although a camera sensing region CSA-ED and a sensor sensing region SSA-ED are illustrated in FIG. 1, the number of sensing regions SA-ED is not limited thereto, and one, three or more sensing regions SA-ED may be defined. In addition, the sensing region SA-ED may be defined in the active region AA-ED and may be a portion of the active region AA-ED. That is, each of the active region AA-ED and each of the individual sensing regions may have a planar area along the plane defined by the first direction DR1 and the second direction DR2 crossing each other. The planar areas of the various sensing regions may be positioned within the planar area of the active region AA-ED, as shown in FIG. 1.

An electronic module EM as a functional component may overlap the sensing region SA-ED. The electronic module EM may receive an external input transferred through the sensing region SA-ED from outside the electronic device ED, or may provide an output through the sensing region SA-ED to outside of the electronic device ED. For example, a camera module (or a camera) may overlap the camera sensing region CSA-ED, and a sensor module (or a sensor) may overlap individual planar areas within an overall planar area of the sensor sensing region SSA-ED.

The electronic device ED may include the active region AA-ED and a peripheral region NAA-ED which is adjacent to the active region AA-ED. The active region AA-ED may be a portion corresponding to an active region AA of a display panel DP that will be described below, and the peripheral region NAA-ED may be a portion corresponding to a peripheral region NAA of the display panel DP.

The peripheral region NAA-ED, which blocks an optical signal, may be a region (or planar area) that is disposed outside the active region AA-ED and closer to an outer edge of the electronic device ED than the active region AA-ED. In an embodiment, the peripheral region NAA-ED may surround the active region AA-ED in the plan view (e.g., a view along the third direction DR3). In an embodiment, the peripheral region NAA-ED may be disposed on a side surface rather than a front (or flat) surface of the electronic device ED. In an embodiment, the peripheral region NAA-ED may be omitted.

The electronic device ED of one embodiment includes a window WM, an upper member UM, the display panel DP, a protective layer PL, a housing HU, and the electronic module EM.

The electronic device ED of one embodiment may include the window WM disposed on the display panel DP, such as facing and/or overlapping the display panel DP along the thickness direction. The window WM provides an outer surface of the electronic device ED. The window WM may cover a front surface of the display panel DP and may protect the display panel DP from an external impact and/or damage such as a scratch. The window WM may be coupled with the upper member UM such as through an adhesive layer.

The window WM may include an optically clear insulating material. For example, the window WM may include a glass film or a synthetic resin film as a base film. The window WM may have a single-layer structure or a multi-layer structure. For example, the window WM may include a plurality of plastic films coupled to each other through an adhesive, or may include a glass film and a plastic film coupled to each other through an adhesive. The window WM may further include window functional layers, such as an anti-fingerprint layer, a phase control layer and a hard coating layer, which are disposed on a transparent film.

In the electronic device ED of one embodiment, the upper member UM may be disposed under the window WM and may be disposed on a display module DM. The upper member UM may include an anti-reflective layer and an input detection sensor (e.g., sensing layer). The anti-reflective layer lowers the reflectance of external light. The input detection sensor senses an external input of a user. The upper member UM may further include an adhesive layer that couples the anti-reflective layer and the input detection sensor to each other.

In the electronic device ED of one embodiment, the display panel DP may be disposed under the upper member UM. The protective layer PL may be disposed under the display panel DP.

The display panel DP may include the active region AA at which the image IM is displayed, and the peripheral region NAA which is adjacent to the active region AA. That is, the front surface of the display panel DP may include the active region AA and a portion of or an entirety of the peripheral region NAA. The active region AA may be a region that is activated depending on an electrical signal and that generates the image IM displayed at the active region AA-ED of the electronic device ED. The image IM may be provided to outside the electronic device ED, such as to a user, through a display screen. The display screen may be provided by the display panel DP and may provide the image IM in the third direction DR3. The protective layer PL may be provided on the lower surface DP-LF of the display panel DP, which is opposite to the display screen or opposite to the image display direction.

The peripheral region NAA may be adjacent to the active region AA. The peripheral region NAA may surround the active region AA, without being limited thereto. A drive circuit and/or drive wiring for driving the active region AA, various types of signal lines or pads that transmit electrical signals to the active region AA from outside thereof, or an electronic element may be disposed in the peripheral region NAA.

The display panel DP includes a first region SA, a second region PA, and a third region NSA. The total planar area of the active region AA of the display panel DP may include the respective planar areas of the first region SA, the second region PA and the third region NSA. The first region SA may be a region or area overlapping the electronic module EM, and the second region PA may be a region surrounding at least a portion of the first region SA. The second region PA may extend from the first region SA, and a boundary may be defined between respective areas of the first region SA and the second region PA. The third region NSA may be a region or area disposed to surround at least a portion of the second region PA. At least a portion of the third region NSA may be spaced apart from the first region SA with the second region PA therebetween. For example, as illustrated in FIG. 2, the second region PA may be defined to surround the entire periphery of the first region SA, and the third region NSA may be defined to surround the entire periphery of the second region PA. That is, the third region NSA may be a remaining planar area of the active region AA, except for the first region SA and the second region PA.

The first region SA may correspond to the sensing region SA-ED of the electronic device ED. The second region PA and the third region NSA may be portions corresponding to the remaining regions other than the first region SA of the active region AA of the display panel DP.

The first region SA may include a first signal transmission region CSA corresponding to the camera sensing region CSA-ED of the electronic device ED and a second signal transmission region SSA corresponding to the sensor sensing region SSA-ED of the electronic device ED. Under the display panel DP, a camera module CAM may be disposed to overlap the first signal transmission region CSA, and a sensor module SM may be disposed to overlap the second signal transmission region SSA. Although not illustrated, an opening may be defined in a partial region of the first region SA of the display panel DP as needed. That is, a portion of the display panel DP that corresponds to the partial region of the first region SA may be penetrated by the opening.

The second region PA may include a first shape region CPA surrounding the first signal transmission region CSA and a second shape region SPA surrounding the second signal transmission region SSA. The first shape region CPA may be defined to surround the entire periphery of the first signal transmission region CSA. The second shape region SPA may be defined to surround the entire periphery of the second signal transmission region SSA. In an embodiment, one of the first shape region CPA and the second shape region SPA may be omitted. That is, the second region PA may not be disposed around one of the first signal transmission region CSA and the second signal transmission region SAA.

Although FIG. 2 illustrates an example that the first region SA includes the first signal transmission region CSA and the second signal transmission region SSA, that is, two transmission regions, and the second region PA includes the first shape region CPA and the second shape region SPA that correspond to the first signal transmission region CSA and the second signal transmission region SSA, respectively, that is, two shape regions, the numbers of first regions SA and second regions PA are not limited thereto. For example, one, three or more first regions SA and one, three or more second regions PA may be defined in the display panel DP. In addition, although FIG. 2 illustrates an example that the first region SA and the second region PA have a circular or quadrangular shape in the plan view, the planar shapes of the first region SA and the second region PA are not limited thereto and may be diversely defined as needed.

On a plane, the areas of the first region SA and the second region PA may be smaller than the area of the third region NSA. The transmittance of the second region PA and the transmittance of the third region NSA may be different from the transmittance of the first region SA. The transmittance of the first region SA may be greater than the transmittance of the second region PA and the transmittance of the third region NSA. As used herein, transmittance may refer to light transmittance, sound transmittance, pressure transmittance, etc. without being limited thereto.

In the display panel DP according to an embodiment, part of a drive circuit or drive wiring for driving a pixel disposed in the first region SA, may be disposed in the peripheral region NAA, or a portion of the second region PA or the third region NSA which are adjacent to the first region SA. The drive circuit or drive wiring may have or define a wiring density at different planar areas. Accordingly, the wiring density in the first region SA may be lower than the wiring density in the second region PA and the wiring density in the third region NSA. However, embodiments are not limited thereto, and the wiring density in the first region SA may be substantially the same as the wiring density in the second region PA and the wiring density in the third region NSA.

The display panel DP may include a light emitting element layer DP-ED (refer to FIG. 4) including an organic light emitting element, a quantum-dot light emitting element, a micro-LED light emitting element, or a nano-LED light emitting element. The light emitting element layer DP-ED (refer to FIG. 4) may be a component that substantially generates an image IM, such as by generating light, emitting light, etc. . . .

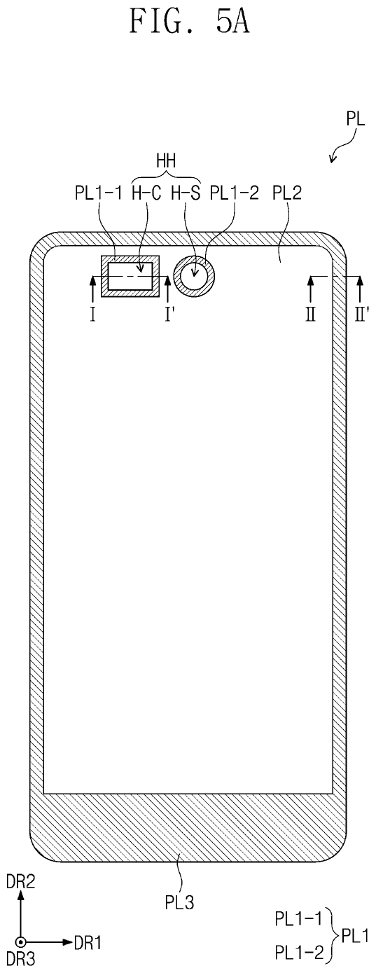

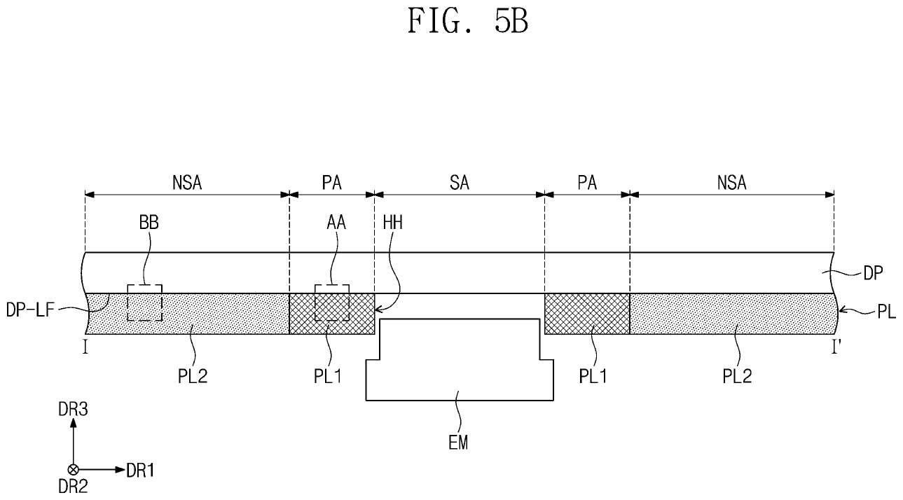

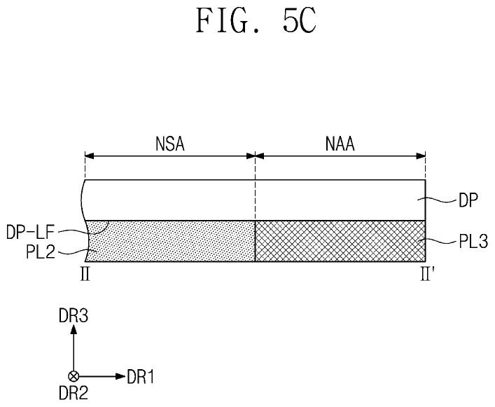

The protective layer PL may be disposed under the display panel DP. The protective layer PL may be a member that supports the display panel DP, absorbs an impact applied to the display panel DP, and performs a heat radiating function of releasing heat generated from components disposed under the display panel DP, for example, the electronic module EM. The protective layer PL includes a first protective part PL1 and a second protective part PL2. The protective layer PL may further include a third protective part PL3. Detailed description about the protective layer PL will be given below with reference to FIG. 5A and the following drawings.

The protective layer PL may have a hole HH defined therein. Portions of the protective layer PL may define the hole HH. The hole HH may be an enclosed opening or enclosed hole having a discrete shape in the plan view. The hole HH may be defined in a region corresponding to the electronic module EM. The hole HH may be defined to overlap the first region SA of the display panel DP. In an embodiment, one or more holes HH may be defined in the protective layer PL. The hole HH as a plurality of individual holes may include a sensor hole H-S and a camera hole H-C.

FIG. 2 illustrates an example that the hole HH as a plurality of holes is defined only in the protective layer PL. However, without being limited thereto, a corresponding opening may be additionally defined in the display panel DP as needed. The hole HH may overlap the electronic module EM. At least a portion of the electronic module EM may extend into the hole HH to be inserted thereinto.

In the electronic device ED according to an embodiment, the electronic module EM may be an electronic part that outputs or receives an optical signal. For example, the electronic module EM may include the camera module CAM and the sensor module SM. The camera module CAM may capture an external image of an external object by receiving external light as the optical signal, through the camera sensing region CSA-ED. In addition, the sensor module SM may be a sensor, such as a proximity sensor or an infrared light emitting sensor, which outputs or receives external light as the optical signal, through the sensor sensing region SSA-ED.

The electronic device ED according to an embodiment may further include a power supply module, a control module, a wireless communication module, an image input module, a sound input module, a sound output module, a memory, and an external interface module, in addition to the above-described electronic module EM. The electronic device ED may include a main circuit board, and the modules may be mounted on the main circuit board, or may be electrically connected to the main circuit board through a flexible circuit board. The power supply module may supply power required for overall operation of the electronic device ED. For example, the power supply module may include a conventional battery device.

Although not illustrated, the electronic device ED may include a flexible circuit board electrically connected with the display panel DP and the main circuit board which is connected to the flexible circuit board. The flexible circuit board may be disposed on the peripheral region NAA of the display panel DP and may be coupled with the display panel DP at the peripheral region NAA. The flexible circuit board may be connected to the main circuit board. The main circuit board may be one electronic part constituting the electronic module EM. A partial region of the peripheral region NAA of the display panel DP that is adjacent to the flexible circuit board may be provided as a bending region of the display panel DP at which the display panel DP is bendable, foldable, rollable, etc. . . . In an embodiment, the bending region may be bent about a bending axis parallel to the first direction DR1. As the display panel DP is bent at the bending region, the flexible circuit board connected to the display panel DP may be disposed to overlap a portion of the display panel DP on the plane.

The electronic device ED of one embodiment may include the display panel DP and the housing HU which is disposed under the electronic module EM and the display panel DP. The electronic module EM and the display panel DP may be accommodated in a receiving space defined by the housing HU. In the electronic device ED according to an embodiment, the window WM and the housing HU may be combined with each other to form the exterior or outer surfaces of the electronic device ED.

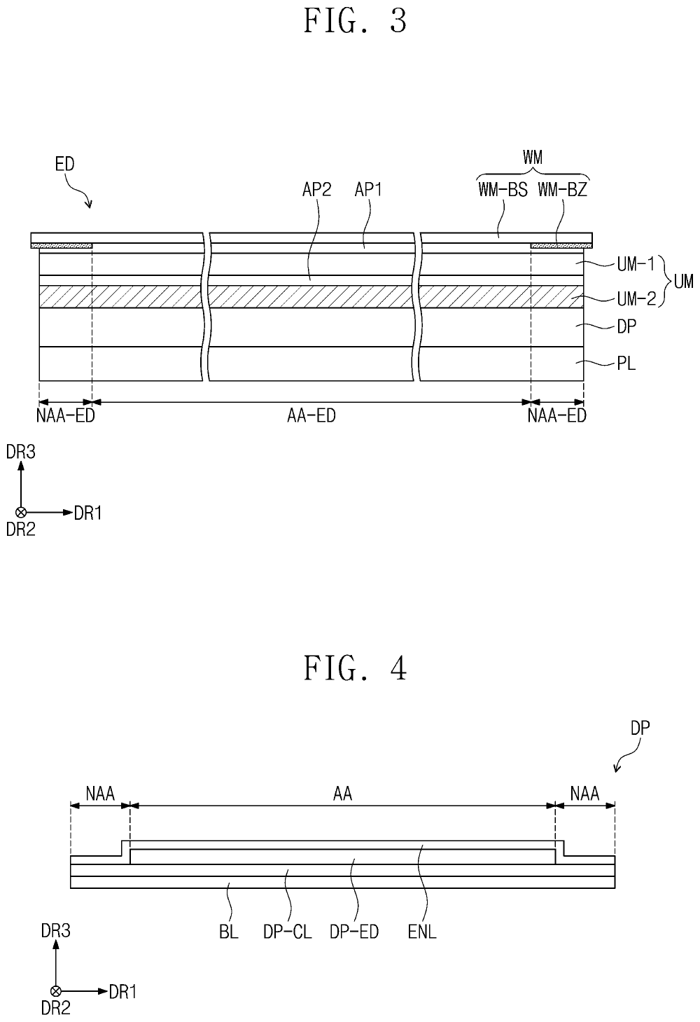

FIG. 3 is a cross-sectional view illustrating some components of the electronic device ED according to an embodiment of the present disclosure.

Referring to FIG. 3, the electronic device ED according to an embodiment of the present disclosure may include the window WM, the upper member UM, the display panel DP, and the protective layer PL. The electronic device ED may include the front surface and the rear surface. The front surface of the electronic device ED may be defined by the window WM, and the rear surface of the electronic device ED may be defined by the protective layer PL. In an embodiment, the rear surface may be defined by the housing HU.

In an embodiment, the window WM may cover the front surface of the display panel DP. The window WM may include a base substrate WM-BS and a bezel pattern WM-BZ. The base substrate WM-BS includes a transparent base material layer such as a glass substrate or a transparent film. The bezel pattern WM-BZ may have a multi-layer structure. The multi-layer structure may include a colored layer and a black light-blocking layer. The colored layer and the black light-blocking layer may be formed or provided through a deposition, printing, or coating process. The bezel pattern WM-BZ may be omitted from the window WM and may be formed or provided on the upper member UM rather than the base substrate WM-BS.

In an embodiment, the upper member UM includes an anti-reflective layer UM-1 and an input sensor UM-2 as an input sensing layer. As illustrated in FIG. 3, the window WM and the anti-reflective layer UM-1 may be coupled to each other through a first adhesive layer AP1, and the anti-reflective layer UM-1 and the input sensor UM-2 may be coupled to each other through a second adhesive layer AP2. In an embodiment, at least one of the first adhesive layer AP1 and the second adhesive layer AP2 may be omitted. For example, the second adhesive layer AP2 may be omitted, and the anti-reflective layer UM-1 may be directly disposed on the input sensor UM-2, such as to form a boundary or interface therebetween.

The anti-reflective layer UM-1 may lower the reflectance of external light. The anti-reflective layer UM-1 may include a phase retarder and/or a polarizer. The anti-reflective layer UM-1 may include a polarizer film or color filters. The color filters may have a predetermined arrangement. The arrangement of the color filters may be determined in consideration of light emission colors of pixels included in the display panel DP. The anti-reflective layer UM-1 may further include a dividing layer adjacent to the color filters.

The input sensor UM-2 may include a plurality of sensing electrodes (not illustrated) for sensing an external input, trace lines (not illustrated) that are connected to the plurality of sensing electrodes, and an inorganic layer and/or an organic layer for insulating/protecting the plurality of sensing electrodes or the trace lines. The input sensor UM-2 may be a capacitive sensor, but is not particularly limited.

The input sensor UM-2 may be directly formed on the display panel DP, such as on a thin film encapsulation layer of the display panel DP through a continuous process when the display panel DP is manufactured. However, without being limited thereto, the input sensor UM-2 may be manufactured as a panel separate from the display panel DP and may be attached to the display panel DP by an adhesive layer.

The protective layer PL may be disposed under the display panel DP. The protective layer PL may be a member that supports the display panel DP and performs a heat radiating function of releasing heat generated from the display panel DP. Detailed description about the protective layer PL will be given below with reference to FIG. 5A and the following drawings.

FIG. 4 is a cross-sectional view of the display panel DP according to an embodiment.

In an embodiment, the display panel DP includes a base layer BL, and a circuit layer DP-CL, the light emitting element layer DP-ED, and an encapsulation layer ENL that are disposed on the base layer BL.

The base layer BL may include a plastic substrate, a glass substrate, a metal substrate, or an organic/inorganic composite substrate. For example, the base layer BL may include at least one polyimide layer. The above-described protective layer PL may be disposed under the base layer BL.

The circuit layer DP-CL includes at least one insulating layer, semiconductor patterns, and conductive patterns. The insulating layer includes at least one inorganic layer and at least one organic layer. The semiconductor patterns and the conductive patterns may constitute signal lines, a pixel drive circuit, and a scan drive circuit. In addition, the circuit layer DP-CL may include a rear metal layer.

The light emitting element layer DP-ED includes a display element, for example, a light emitting element. For example, the light emitting element may be an organic light emitting element, a quantum-dot light emitting element, a micro-LED light emitting clement, or a nano-LED light emitting element. The light emitting element layer DP-ED may further include an organic layer such as a pixel defining layer.

The light emitting element layer DP-ED may be disposed in the active region AA, such as within pixels of the display panel DP. The peripheral region NAA may be disposed around the active region AA and may surround the active region AA, and no light emitting element may be disposed in the peripheral region NAA. The active region AA may define a display area while the peripheral region NAA defines a non-display area. The light emitting element layer DP-ED may be connected to the circuit layer DP-CL, such as to generate light, emit light and/or generate an image IM.

The encapsulation layer ENL may be disposed on the light emitting element layer DP-ED and may cover the light emitting element layer DP-ED. The encapsulation layer ENL may be disposed on the circuit layer DP-CL to seal the light emitting element layer DP-ED. The encapsulation layer ENL may be a thin film encapsulation layer including a plurality of organic thin films and a plurality of inorganic thin films. The encapsulation layer ENL may include a thin film encapsulation layer including a stacked structure of an inorganic layer/an organic layer/an inorganic layer. The stacked structure of the encapsulation layer ENL is not particularly limited.

FIG. 5A is a plan view of the protective layer PL according to an embodiment of the present disclosure. FIGS. 5B and 5C are cross-sectional views of portions of the electronic device ED according to embodiments of the present disclosure. FIG. 5B illustrates a cross-section corresponding to line I-I′ illustrated in FIG. 5A, and FIG. 5C illustrates a cross-section corresponding to line II-II′ illustrated in FIG. 5A.

Referring to FIGS. 2 and 5A together, the protective layer PL according to an embodiment of the present disclosure includes the first protective part PL1 and the second protective part PL2. The first protective part PL1 and the second protective part PL2 may be disposed on the lower surface of the display panel DP.

The first protective part PL1 may correspond to the second region PA of the display panel DP. The second protective part PL2 may correspond to the third region NSA of the display panel DP. The first protective part PL1 may overlap the second region PA on the plane. The first protective part PL1 may be disposed on the lower surface of the display panel DP to overlap the second region PA. The second protective part PL2 may overlap the third region NSA on the plane. The second protective part PL2 may be disposed on the lower surface of the display panel DP to overlap the third region NSA.

The protective layer PL may have the hole HH defined therein. The hole HH may be defined in a region corresponding to the electronic module EM. The hole HH may be defined to overlap the first region SA of the display panel DP. The hole HH may be a through-hole which extends completely through a thickness of the protective layer PL. A portion of the lower surface DP-LF of the display panel DP may be exposed to outside the protective layer PL by the through-hole. In an embodiment, the hole HH may extend partially into the thickness of the protective layer PL, to maintain a thickness portion thereof within the hole HH. The partially-extended hole may be open at the upper surface of the protective layer PL which is closest to the display panel DP and/or at the lower surface of the protective layer PL which is opposite to the upper surface (or furthest from the display panel DP). In an embodiment, one or more holes HH may be defined in the protective layer PL. The plurality of holes HH may include the sensor hole H-S and the camera hole H-C. Each of the holes HH may extend completely through a thickness of the protective layer PL, without being limited thereto.

The first protective part PL1 may be disposed to surround the hole HH defined in the protective layer PL. An inner surface or sidewall of the first protective part PL1 may define the hole HH. The first protective part PL1 may be defined to extend around the hole HH to surround the entire periphery of the hole HH. The first protective part PL1 may include a first pattern PL1-1 surrounding the camera hole H-C and a second pattern PL1-2 surrounding the sensor hole H-S.

The second protective part PL2 may be disposed to overlap the third region NSA of the display panel DP and may be disposed to surround at least a portion of the first protective part PL1. At least a portion of the second protective part PL2 may be spaced apart from the hole HH with the first protective part PL1 therebetween. For example, as illustrated in FIGS. 2 and 5A, the first protective part PL1 may be defined to surround the entire periphery of the hole HH, and the second protective part PL2 may be defined to surround the entire periphery of the first protective part PL1. The entire second protective part PL2 may be spaced apart from the hole HH with the first protective part PL1 therebetween. The second protective part PL2 may be spaced apart from the camera hole H-C with the first pattern PL1-1 therebetween and may be spaced apart from the sensor hole H-S with the second pattern PL1-2 therebetween.

Referring to FIGS. 2, 5A, and 5B together, the electronic device ED according to an embodiment of the present disclosure may include the display panel DP and the protective layer PL which is disposed under the display panel DP. In the electronic device ED according to an embodiment of the present disclosure, the protective layer PL having a single layer form (e.g., a monolayer) may be provided on the lower surface DP-LF of the display panel DP which is closest to the protective layer PL. The protective layer PL may be a member or layer that supports the display panel DP, absorbs an impact applied to the display panel DP from outside thereof, and performs a heat radiating function of releasing heat generated from components disposed under the display panel DP, for example, the electronic module EM. As the protective layer PL having a single layer form simultaneously performs the impact absorbing function and the heat radiating function in a single thickness portion of the electronic device ED, the thickness of the electronic device ED may be reduced, parts may be simplified, and process efficiency in the manufacture of the electronic device ED may be increased.

The protective layer PL may be directly disposed under the display panel DP. The protective layer PL may make contact with the lower surface DP-LF of the display panel DP, such as to form an interface therebetween. A separate adhesive member may not be disposed between the protective layer PL and the display panel DP.

In cross-section, the first protective part PL1 and the second protective part PL2 may be disposed side by side along the first direction DR1 and/or the second direction DR2. That is, the first protective part PL1 and the second protective part PL2 arranged along the display panel DP are coplanar with each other. The first protective part PL1 overlapping the second region PA of the display panel DP and the second protective part PL2 overlapping the third region NSA of the display panel DP may be disposed side by side such that one side surface of the first protective part PL1 and one side surface of the second protective part PL2 face each other and make contact with each other. In an embodiment, on the plane defined by the first direction DR1 and the second direction DR2, the first protective part PL1 and the second protective part PL2 may not overlap each other. As not overlapping, elements may be adjacent to each other along the plane.

The first protective part PL1 and the second protective part PL2 may be provided through separate processes. The protective layer PL of one embodiment may be formed by providing both a resin material from which the first protective part PL1 is provided and a resin material from which the second protective part PL2 is provided, to the lower surface DP-LF of the display panel DP, such as through separate processes. In an embodiment, the first protective part PL1 may be formed on the lower surface DP-LF of the display panel DP that corresponds to the second region PA, and the second protective part PL2 may be formed on the lower surface DP-LF of the display panel DP that corresponds to the third region NSA. In an embodiment, the second protective part PL2 may be formed after the first protective part PL1 is formed, however, is not limited thereto.

In the electronic device ED according to an embodiment, the first protective part PL1 may be disposed to surround the hole HH defined in the protective layer PL, and the second protective part PL2 may be spaced apart from the hole HH with the first protective part PL1 therebetween. That is, the first protective part PL1 may be disposed closest to the hole HH defined in the protective layer PL, and the second protective part PL2 may be spaced apart from the hole HH.

The first protective part PL1 as a light blocking portion of the protective layer PL may be a part disposed under the second region PA of the display panel DP and disposed adjacent to (e.g., closest to) the hole HH defined to correspond to the first region SA where the electronic module EM is disposed. As the first protective part PL1 is disposed adjacent to the hole HH, a detailed shape of the protective layer PL corresponding to the first region SA where the electronic module EM is disposed may be implemented.

The second protective part PL2 as an impact-absorbing portion, light blocking portion and/or a heat dissipating portion of the protective layer PL may be a component that is disposed under the third region NSA of the display panel DP and that absorbs an impact applied to the display panel DP and releases heat generated from the display panel DP. As the second protective part PL2 is disposed to overlap the third region NSA corresponding to most of the active region AA, heat generated from the display panel DP may be effectively released by the second protective part PL2.

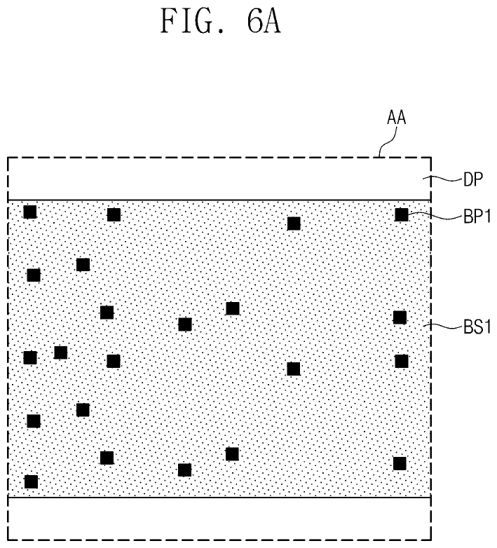

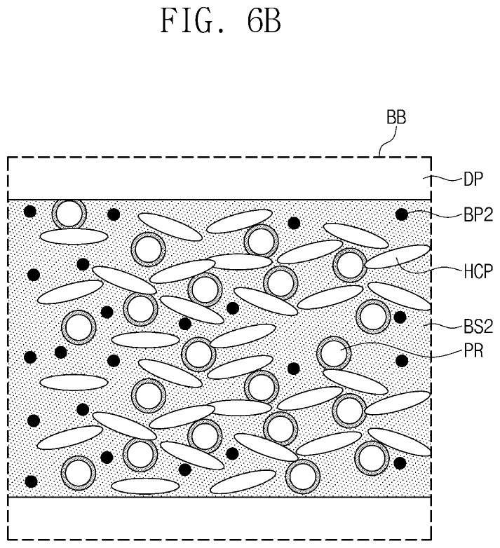

FIGS. 6A and 6B are enlarged cross-sectional views of portions of the electronic device ED according to embodiments of the present disclosure. FIG. 6A is an enlarged cross-sectional view of region AA illustrated in FIG. 5B. FIG. 6A is a detailed cross-sectional view illustrating the first protective part PL1 included in the protective layer PL of one embodiment. FIG. 6B is an enlarged cross-sectional view of region BB illustrated in FIG. 5B. FIG. 6B is a detailed cross-sectional view illustrating the second protective part PL2 included in the protective layer PL of one embodiment.

Referring to FIGS. 6A and 6B, the first protective part PL1 may include a UV (ultraviolet) curable resin. The first protective part PL1 may include a first base resin BS1 including the UV curable resin. The first base resin BS1 may include at least one of an acrylate-based resin, a urethane-based resin, a fluorine-based resin, an epoxy-based resin, a polyester-based resin, a polyamide-based resin and a silicone-based resin that has UV curing characteristics.

The first protective part PL1 may include a first light blocking material BP1. The first protective part PL1, which includes the first light blocking material BP1, may be black in color and may have a property of blocking light. The first light blocking material BP1 included in the first protective part PL1 may include a UV transmitting material. As the first light blocking material BP1 includes a UV transmitting pigment, the UV curable resin included in the first protective part PL1 may be completely cured (e.g., without an uncured portion) in a process of forming the first protective part PL1. The first light blocking material BP1 may include, for example, iron oxide, carbon nanotube, or carbon black that has UV transmitting characteristics. The first protective part PL1 within the protective layer PL may be a cured form of the UV curable resin (e.g., a cured resin) which has the first light blocking material BP1.

In an embodiment, the first protective part PL1 may further include an additive. The additive may be a photo-initiator that induces a UV curing reaction (e.g., a UV curing inducing material).

In an embodiment, the second protective part PL2 may include a heat radiating material HCP. The heat radiating material HCP included in the second protective part PL2 may include, for example, at least one of a thermally conductive metal, a carbon-based heat radiating material and a thermally conductive polymer. The heat radiating material HCP included in the second protective part PL2 may include a thermally conductive metal such as aluminum, copper, silver, or magnesium. Alternatively, the heat radiating material HCP included in the second protective part PL2 may include a carbon-based heat radiating material such as graphene, graphite, or carbon nanotube. In another case, the heat radiating material HCP included in the second protective part PL2 may include a thermally conductive polymer such as ultra high molecular polyethylene.

The heat radiating material HCP within the second protective part PL2 may have an average diameter of about 200 micrometers (μm) or less. For example, the heat radiating material HCP may have an average diameter of about 5 μm to about 200 μm. In FIG. 6B, the heat radiating material HCP is illustrated as having a constant diameter. However, without being limited thereto, the heat radiating material HCP may have a substantially monodisperse distribution of sizes or a polydisperse distribution obtained by mixing a plurality of particles having a monodisperse distribution. When the heat radiating material HCP has an average diameter of less than about 5 μm, it may be difficult to implement the heat radiating characteristics of the protective layer PL, and when the heat radiating material HCP has an average diameter of more than about 200 μm, the distribution characteristics of the heat radiating material HCP in the second protective part PL2 may be deteriorated, and therefore it may be difficult to secure uniform thin film characteristics. In an embodiment, two or more heat radiating materials of different types or sizes may be mixed and used as the heat radiating material HCP.

The amount of the heat radiating material HCP may be about 90 weight percent (wt %) or less with regard to the total weight of the second protective part PL2. For example, the amount of the heat radiating material HCP may range from about 50 wt % to about 90 wt % with regard to the total weight of the second protective part PL2. When the amount of the heat radiating material HCP is less than about 90 wt %, the heat radiating characteristics of the second protective part PL2 may be reduced. In addition, when the amount of the heat radiating material HCP exceeds about 50 wt %, the impact absorbing characteristics of the second protective part PL2 may be excessively deteriorated, which may lead to deterioration in the impact absorbing characteristics of the entire protective layer PL. Therefore, a defect such as damage to the display panel DP due to an external impact may occur.

The second protective part PL2 may further include a second base resin BS2. The second base resin BS2 may include a thermosetting resin. In an embodiment, the second base resin BS2 may include at least one of an acrylate-based resin, a urethane-based resin, a fluorine-based resin, an epoxy-based resin, a polyester-based resin, a polyamide-based resin and a silicone-based resin.

In an embodiment, the second protective part PL2 may further include a second light blocking material BP2. The second protective part PL2 including the second light blocking material BP2 may be black in color. The second light blocking material BP2 included in the second protective part PL2 may be different from the first light blocking material BP1 included in the first protective part PL1. For example, the second light blocking material BP2 may be a black pigment or a black dye. Alternatively, the second light blocking material BP2 may be a carbon-based material such as graphene or graphite.

In an embodiment, at least one of the first protective part PL1 and the second protective part PL2 may include the light blocking material BP1 or BP2, and thus the protective layer PL may block light emitted from the display panel DP from being leaked below the display panel DP. That is, the protective layer PL may not only protect the display panel DP from an external impact, but may also perform a light blocking function of blocking light emitted from the display panel DP. The protective layer PL included in the electronic device ED of one embodiment may not include a separate light blocking layer or sheet along a thickness direction of the display panel DP. As the protective layer PL does not include a separate light blocking sheet, the thickness of the protective layer PL may be reduced, and weight reduction and slimness of the electronic device ED may be achieved.

The second protective part PL2 may further include at least one of a foaming agent and an clastic hollow particle. For example, the second protective part PL2 may further include the foaming agent PR. As the foaming agent PR or the elastic hollow particle is included in the second protective part PL2, the impact absorbing characteristics of the second protective part PL2 may be improved. When the second protective part PL2 includes a particulate additive such as the heat radiating material HCP, the impact absorbing characteristics of the second protective part PL2 may be deteriorated. However, as the second protective part PL2 of one embodiment includes the foaming agent or the elastic hollow particle for absorbing an impact, the deterioration in the impact absorbing characteristics of the second protective part PL2 may be compensated for, and thus the impact absorbing characteristics of the protective layer PL may be prevented from being deteriorated.

In an embodiment, the second protective part PL2 may further include an additive. The additive may be a thermal initiator such as a material that induces a heat curing reaction.

In an embodiment, the second protective part PL2 may include the second base resin BS2, and the heat radiating material HCP, the second light blocking material BP2 and the foaming agent PR that are dispersed in the second base resin BS2. As the second protective part PL2 includes the second base resin BS2, the heat radiating material HCP, the second light blocking material BP2, and the foaming agent PR, the second protective part PL2 may perform multiple functions in the electronic device. For example, the second protective part PL2 may support the display panel DP. The second protective part PL2 may protect the display panel DP from a physical impact applied from the outside. In addition, the protective layer PL may perform a heat radiating function of releasing heat generated from the display panel DP. The protective layer PL may also perform a light blocking function of blocking light emitted from the display panel DP. However, without being limited thereto, the second protective part PL2 may additionally perform other functions in the electronic device ED depending on characteristics such as the material included in the second protective part PL2 and the thickness thereof. For example, the second protective part PL2 may further include a material having a shielding function. As the second protective part PL2 includes an electromagnetic shielding material, the second protective part PL2 may have a function of shielding electromagnetic waves.

In an embodiment, the first protective part PL1 may include the first base resin BS1 and the first light blocking material BP1 which is dispersed in the first base resin BS1. In an embodiment, the first protective part PL1 does not include a heat radiating material. In an embodiment, the first protective part PL1 may be constituted by only the first base resin BS1 and the first light blocking material BP1. In an embodiment, the first protective part PL1 may be constituted by only the first base resin BS1, the first light blocking material BP1, and the additive. The first protective part PL1 may be constituted by only the first base resin BS1, the first light blocking material BP1, and the initiator. The first protective part PL1 may be a single layer (e.g., a monolayer or a single thickness portion) constituted by the first base resin BS1, the first light blocking material BP1, and the initiator.

When the first protective part PL1 includes the first base resin BS1 and the first light blocking material BP1, the first protective part PL1 may perform multiple functions in the electronic device. For example, the first protective part PL1 may support the display panel DP. In addition, the first protective part PL1 may perform a light blocking function. Alternatively, the first protective part PL1 may further include a material having a shielding function. As the first protective part PL1 includes an electromagnetic shielding material, the first protective part PL1 may have a function of shielding electromagnetic waves. However, without being limited thereto, the first protective part PL1 may additionally perform other functions in the electronic device depending on characteristics such as the thickness and the material of the first protective part PL1.

The heat radiating material HCP may have a size which is larger than other particles such as a light blocking material. As the first protective part PL1 includes the UV curable resin and does not include a relatively large-diameter particulate material such as a heat radiating material HCP (e.g., excludes the heat radiating material HCP), the first protective part PL1 may be formed through an ink-jet process or a process such as dispensing to have a specific shape. Accordingly, the first protective part PL1 adjacent to the hole HH may be formed to have a shape precisely corresponding to the shape of the hole HH, and thus the reliability of the electronic device ED may be improved. That is, a shape of the first protective part PL1 adjacent to the hole HH may correspond to each other. In an embodiment, for example, an electronic device ED may include a display panel DP including a display area (e.g., the active region AA) and a peripheral region NAA adjacent to each other, and the display area including a first region SA corresponding to an electronic module EM having a shape, a second region PA which extends from the first region SA, and a third region NSA which is spaced apart from the first region SA with the second region therebetween PA. Here, the protective layer PL is disposed facing the display panel DP and includes a first protective pattern (e.g., the first protective part PL1) which is directly adjacent to the first region SA, overlaps the second region PA and has a shape corresponding to that of the electronic module EM (e.g., in a plan view, for example), a second protective pattern (e.g., the second protective part PL2) which is coplanar with the first protective pattern, adjacent to the first protective pattern and overlaps the third region NSA. The second protective pattern is disposed having a heat radiating material while an entirety of the first protective pattern which overlaps the second region is disposed excluding the heat radiating material.

In an embodiment, the second protective part PL2 overlapping the third region NSA corresponding to most of the active region AA includes a thermosetting resin and a relatively large-diameter heat radiating particle, but it is unnecessary to implement a detailed shape of the second protective part PL2. Accordingly, the second protective part PL2 may be formed through a coating process such as slit coating or screen printing other than the ink-jet process or the process such as dispensing. The second protective part PL2, which includes the particulate material such as the heat radiating material HCP and the foaming agent PR, may protect the display panel DP from a physical impact applied from outside the display panel DP and may perform a heat radiating function of releasing heat generated from the display panel DP.

In addition to the second protective part PL2, the first protective part PL1 may also further include at least one of a foaming agent and an elastic hollow particle. For example, the first protective part PL1 may further include the foaming agent. As the foaming agent or the elastic hollow particle is included in the first protective part PL1, the impact absorbing characteristics of the first protective part PL1 may be improved.

Referring again to FIGS. 5A and 5B, the thicknesses of the first protective part PL1 and the second protective part PL2 which are coplanar with each other may range from about 50 μm to about 300 μm. For example, the thicknesses of each of the first protective part PL1 and the second protective part PL2 may range from about 100 μm to about 200 μm. In an embodiment, the thickness of the second protective part PL2 may be equal to or smaller than the thickness of the first protective part PL1. For example, the thickness of the first protective part PL1 and the thickness of the second protective part PL2 may be substantially the same as each other.

The electronic module EM of one embodiment is disposed to overlap the first region SA of the display panel DP. The hole HH of the protective layer PL may overlap the electronic module EM, and at least a portion of the electronic module EM may extend into the hole HH. For example, the electronic module EM may be a camera module including a lens adjacent to (or closest to) the display panel DP. In an embodiment, the lens of the camera module may be inside the hole HH. Referring to FIG. 5B for example, the hole HH may be a space or gap into which the electronic module EM extends. A portion of the electronic module EM may remain outside of the protective layer PL1 with another portion of the electronic module EM being inside of the hole HH.

Referring to FIGS. 2, 5A, and 5C together, the protective layer PL may further include the third protective part PL3 coplanar with each of the first and second protective parts PL1 and PL2. The third protective part PL3 may correspond to the peripheral region NAA of the display panel DP. The third protective part PL3 may overlap the peripheral region NAA on the plane. The third protective part PL3 may be disposed extended along the lower surface of the display panel DP to overlap the peripheral region NAA.

As being coplanar, the first, second and third protective parts PL1, PL2 and PL3 may be in a same layer (e.g., the protective layer PL). As being in a same layer, elements may be formed in a same process and/or include a same material as each other, elements may be respective portions of a same material layer, elements may be on a same layer by forming an interface with a same underlying or overlying layer, etc., without being limited thereto. Herein, the first, second and third protective parts PL1, PL2 and PL3 may each form an interface with the display panel DP, to be in a same layer or coplanar with each other.

In cross-section, the second protective part PL2 and the third protective part PL3 may be disposed side by side in the first direction DR1 or the second direction DR2, such as to be coplanar with each other. The second protective part PL2 overlapping the third region NSA of the display panel DP and the third protective part PL3 overlapping the peripheral region NAA may be disposed side by side such that one side surface of the second protective part PL2 and one side surface of the third protective part PL3 which face each make contact with each other. In an embodiment, on the plane defined by the first direction DR1 and the second direction DR2, the second protective part PL2 and the third protective part PL3 may not overlap each other.

The second protective part PL2 and the third protective part PL3 may be provided through separate processes. The protective layer PL of one embodiment may be formed by providing each of a resin material from which the second protective part PL2 is provided and a resin material from which the third protective part PL3 is provided, to the lower surface DP-LF of the display panel DP through separate respective processes. In an embodiment, the second protective part PL2 may be formed on the lower surface DP-LF of the display panel DP that corresponds to the third region NSA, and the third protective part PL3 may be formed on the lower surface DP-LF of the display panel DP that corresponds to the peripheral region NAA. In an embodiment, the second protective part PL2 may be formed after the third protective part PL3 is formed.

The third protective part PL3 may include the same material as the first protective part PL1. In an embodiment, likewise to the first protective part PL1, the third protective part PL3 may include a UV curable resin. The description of the material included in the above-described first protective part PL1 may be identically applied to the material included in the third protective part PL3.

As the third protective part PL3 includes the UV curable resin and does not include a relatively large-diameter particulate material such as a heat radiating material, the third protective part PL3 may be formed through an ink-jet process or a process such as dispensing to have a specific shape. Accordingly, the third protective part PL3 corresponding to the peripheral region NAA corresponding to the outer portion of the display panel DP may be formed to have a shape precisely corresponding to the shape of the peripheral region NAA, and thus the reliability of the electronic device ED may be improved.

The third protective part PL3 may have a thickness of about 50 μm to about 300 μm. For example, the third protective part PL3 may have a thickness of about 100 μm to about 200 μm. In an embodiment, the thickness of the third protective part PL3 may be equal to or smaller than the thickness of the second protective part PL2. For example, the thickness of the third protective part PL3 and the thickness of the second protective part PL2 may be substantially the same as each other.

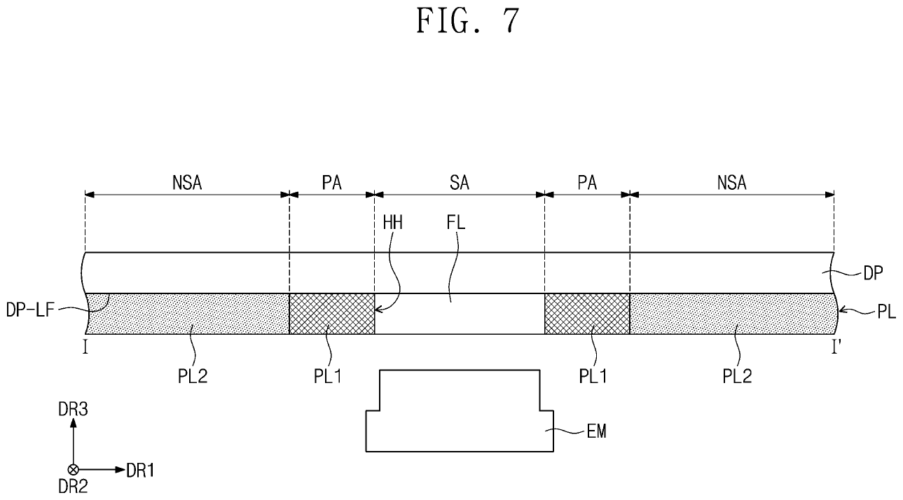

FIG. 7 is a cross-sectional view of a portion of the electronic device ED according to an embodiment of the present disclosure. FIG. 7 illustrates a cross-section of the electronic device ED of one embodiment in the cross-section corresponding to FIG. 5B.

Referring to FIGS. 2, 5A, and 7, the electronic device ED according to an embodiment may further include a filling layer FL. The filling layer FL may be disposed in the hole HH defined in the protective layer PL. The filling layer FL may completely fill the volume of the hole HH. Since the filling layer FL may occupy a volume of the hole HH, the electronic module EM may not extend into the hole HH and may remain outside of the protective layer PL.

The filling layer FL may be disposed in the hole HH to overlap the electronic module EM. The filling layer FL may serve to fill the hole HH, adjust the transmittance of the first region SA, and prevent a phenomenon, such as reflection interference, which deteriorates optical characteristics of the electronic module EM. The filling layer FL may have a property of transmitting light.

The first protective part PL1 and the filling layer FL may be disposed side by side in the first direction DR1 or the second direction DR2, so as to be coplanar with each other. The first protective part PL1 overlapping the second region PA of the display panel DP and the filling layer FL overlapping the first region SA may be disposed side by side such that one side surface of the first protective part PL1 and one side surface of the filling layer FL make contact with each other. On the plane defined by the first direction DR1 and the second direction DR2, the first protective part PL1 and the filling layer FL may not overlap each other.

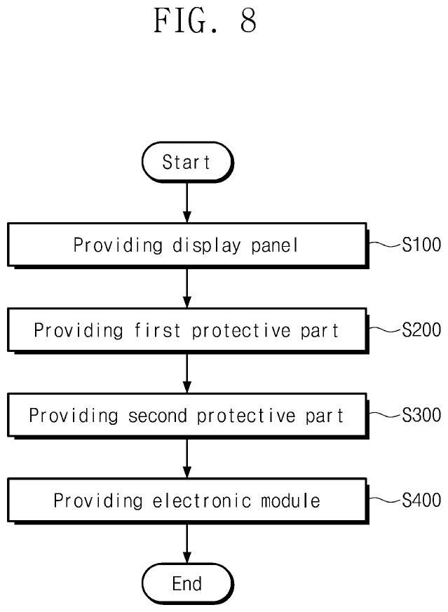

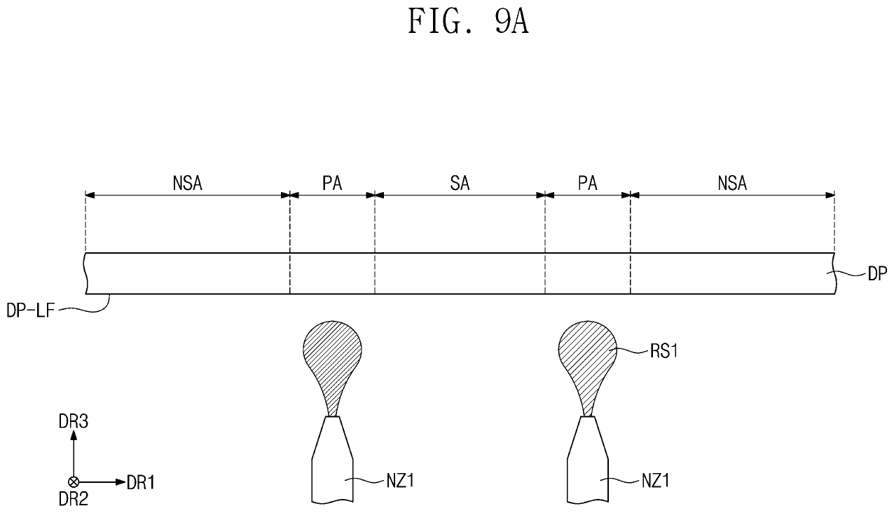

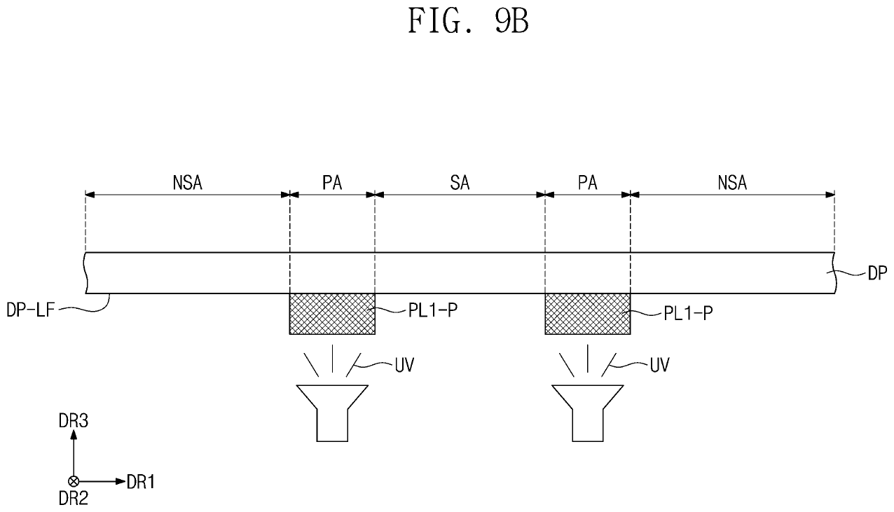

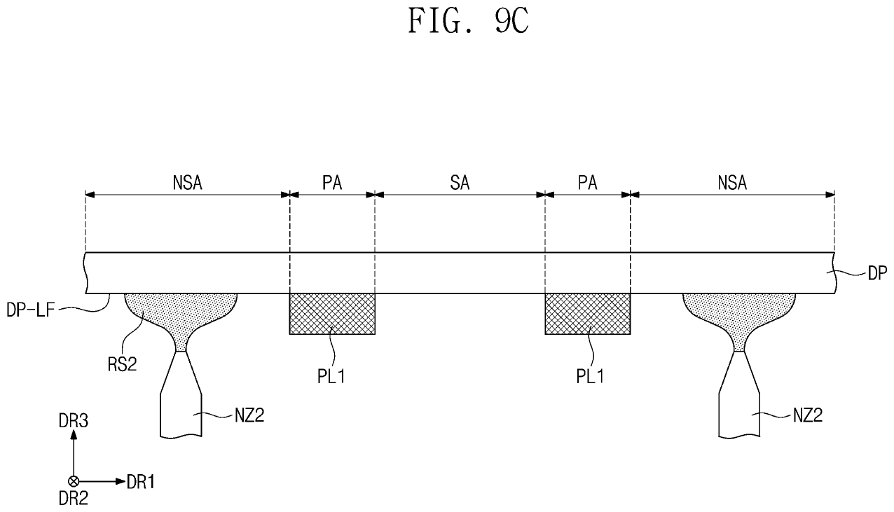

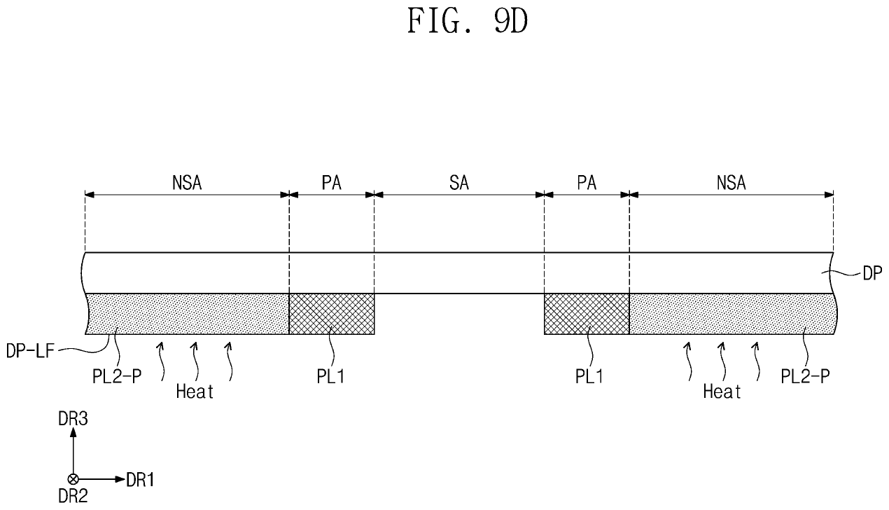

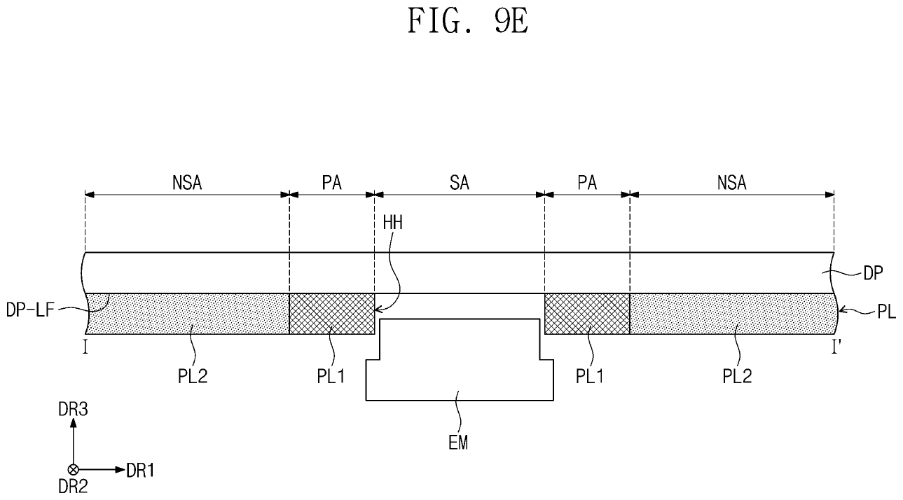

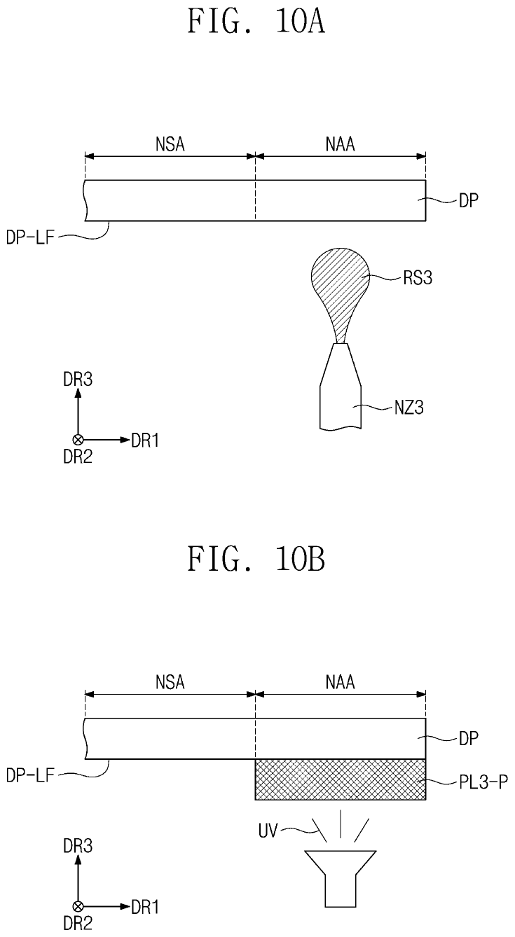

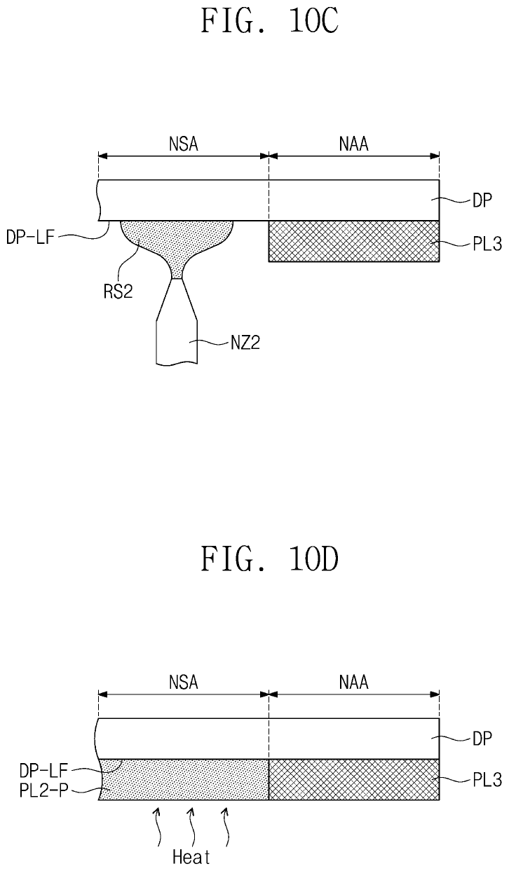

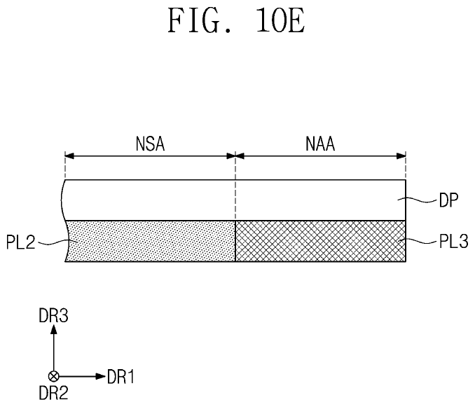

FIG. 8 is a flowchart illustrating a method of manufacturing (or providing) the electronic device ED according to an embodiment. FIGS. 9A to 9E are cross-sectional views illustrating structures and processes in the method of manufacturing the electronic device ED according to an embodiment of the present disclosure. FIGS. 10A to 10E are cross-sectional views illustrating structures and processes in the method of manufacturing the electronic device ED according to an embodiment of the present disclosure. The method of manufacturing the electronic device ED may be a method of manufacturing the electronic device ED described with reference to FIGS. 1 to 7. In an embodiment, a method of manufacturing the electronic device ED including the protective layer PL disposed under the display panel DP is provided. In describing the method of manufacturing the electronic device ED with reference to FIGS. 8, 9A to 9E, and 10A to 10E, components identical to those described above will be assigned with identical reference numerals, and detailed descriptions thereabout will be omitted.

Referring to FIG. 8, the method of manufacturing the electronic device ED includes providing the display panel DP (S100), forming (or providing) the first protective part PL1 (S200), forming (or providing) the second protective part PL2 (S300) and providing the electronic module ED (S400).

FIGS. 9A to 9E are schematic cross-sectional views illustrating providing of the first protective part PL1 and providing of the second protective part PL2 in the method of manufacturing the electronic device ED. In FIGS. 9A to 9E, structures corresponding to FIG. 5B described above are schematically illustrated.

FIGS. 9A and 9B schematically illustrate S200 of forming the first protective part PL1 by providing a first resin RS1 to the lower surface DP-LF of the display panel DP, such that the first resin RS1 overlaps the second region PA. The providing of the first protective part PL1 may include applying the first resin RS1 to the lower surface DP-LF of the display panel DP and curing the applied first resin using UV light to provide a first cured portion PL1-P. FIG. 9A schematically illustrates the applying the first resin RS1 to the lower surface DP-LF of the display panel DP, and FIG. 9B schematically illustrates curing the applied first resin. The cured resin may define a discrete pattern of the first resin material which has side surfaces facing each other along the display panel DP.

Referring to FIGS. 8, 9A, and 9B, the first resin RS1 may be applied to the lower surface DP-LF of the display panel DP through a first nozzle NZ1. The first resin RS1 may be provided to a portion or area of the display panel DP which corresponds to the second region PA. The first resin RS1 may be provided to the entire second region PA, such as to an entire area thereof which is defined along the DR1-DR2 plane. The first resin RS1 may be provided to a portion of the display panel DP other than the first region SA and the third region NSA of the active region AA (refer to FIG. 2).

In an embodiment, the first resin RS1 may be directly applied to the lower surface DP-LF of the display panel DP. Accordingly, a separate adhesive layer is not required between the display panel DP and the first protective part PL1, and thus the process reliability of the electronic device ED may be improved.

To implement a shape in which the first protective part PL1 is specifically formed only in the second region PA, the applying the first resin RS1 may be performed through a specific process. The applying the first resin RS1 may be performed through, for example, an ink-jet process or a process such as dispensing. As the applying the first resin RS1 is performed through the ink-jet process or the dispensing process, the first resin RS1 may be uniformly applied to correspond to the local second region PA. Accordingly, the process reliability of the electronic device ED may be improved.

The first resin RS1 may include a UV curable resin. The first resin RS1 may include a first base resin BS1 including the UV curable resin. The first base resin BS1 may include at least one of an acrylate-based resin, a urethane-based resin, a fluorine-based resin, an epoxy-based resin, a polyester-based resin, a polyamide-based resin and a silicone-based resin that has UV curing characteristics. The first base resin BS1 included in the first resin RS1 as uncured material may be in a liquid form before curing.

The first resin RS1 may include a first light blocking material BP1. The first resin RS1, which includes the first light blocking material BP1, may be black in color and may have a property of blocking light. The first light blocking material BP1 included in the first resin RS1 may include a UV transmitting material. As the first light blocking material BP1 includes a UV transmitting pigment, the UV curable resin included in the first resin RS1 may be completely cured without an uncured portion in the process of forming the first cured portion PL1-P. The first light blocking material BP1 may include, for example, iron oxide, carbon nanotube, or carbon black that has UV transmitting characteristics.

In an embodiment, the first resin RS1 may further include an additive. The additive may be a photo-initiator that induces a UV curing reaction.

The first resin RS1 does not include a heat radiating material HCP. Since the first resin RS1 is applied to the second region PA, which corresponds to a portion that is relatively local when compared to the third region NSA in the display panel DP, to have a specific shape, a process such as ink-jet printing or dispensing may be used. When the first resin RS1 includes a heat radiating material HCP, problems such as a nozzle clogging phenomenon and a heterogeneous surface may occur due to the heat radiating material HCP. However, in the present disclosure, the first resin RS1 for forming the first protective part PL1 does not include a heat radiating material HCP. Accordingly, the coating reliability of the first resin RS1 may be improved, the nozzle clogging phenomenon may be prevented, and a uniform thin film of the first resin material may be formed. Thus, the process reliability of the electronic device ED may be improved.

Referring to FIGS. 8, 9B, and 9C, the curing the first resin RS1 may include providing light UV to the first resin RS1 on the display panel DP. The first resin RS1 may be cured by providing the light UV to the first resin RS1 provided on the lower surface DP-LF of the display panel DP. The light UV may be UV light. For example, the light UV may be UV light having a central wavelength in a wavelength range of about 100 nanometers (nm) to about 400 nm. The first resin RS1 may be photo-cured by the UV light UV. As the first resin RS1 includes the UV curable resin, the first resin RS1 may be cured by the UV light to form the first protective part PL1 from the first cured portion PL1-P.

FIGS. 9C and 9D schematically illustrate forming the second protective part PL2 by providing a second resin RS2 to the lower surface DP-LF of the display panel DP which has the first protective part PL1, such that the second resin RS2 overlaps the third region NSA. The forming the second protective part PL2 may include applying the second resin RS2 to the lower surface DP-LF of the display panel DP and curing the applied second resin such as by using heat. FIG. 9C schematically illustrates the applying the second resin RS2 to the lower surface DP-LF of the display panel DP, and FIG. 9D schematically illustrates the curing the second resin RS2.

Referring to FIGS. 8, 9C, and 9D, the second resin RS2 for forming the second protective part PL2 may be applied after forming the first protective part PL1. Referring to FIG. 9C, the second resin RS2 may be applied to the lower surface DP-LF of the display panel DP through a second nozzle NZ2. The second resin RS2 may be provided to a portion corresponding to the third region NSA in the display panel DP. In an embodiment, the second resin RS2 may be directly applied to the lower surface DP-LF of the display panel DP. Accordingly, a separate adhesive layer is not required between the display panel DP and the second protective part PL2, and thus the process reliability of the electronic device ED may be improved.

The forming the second protective part PL2 may be performed by various methods. The step of forming the second protective part PL2 may be performed by at least one of spin coating, slit coating, jet printing, metal mask printing and screen printing. For example, the forming the second protective part PL2 may be performed by screen printing.

In an embodiment, the first protective part PL1 and the second protective part PL2 may be formed through different processes. In an embodiment, the process of applying the first resin RS1 may be performed through an ink-jet process or a dispensing process, and the process of applying the second resin RS2 may be performed by screen printing.

The second resin RS2 may include a heat radiating material HCP. The second resin RS2 may include a second base resin BS2 and the heat radiating material HCP dispersed in the second base resin BS2. The second base resin BS2 may include at least one of an acrylate-based resin, a urethane-based resin, a fluorine-based resin, an epoxy-based resin, a polyester-based resin, a polyamide-based resin and a silicone-based resin. The second base resin BS2 may be an acrylate-based resin, a urethane-based resin, a fluorine-based resin, an epoxy-based resin, a polyester-based resin, a polyamide-based resin, or a silicone-based resin provided in the form of a monomer or an oligomer. The second base resin BS2 included in the second resin RS2 may be in a liquid form before curing and may include a thermosetting resin.

In an embodiment, the second resin RS2 may further include at least one of a light blocking material and a foaming agent, in addition to the heat radiating material HCP. For example, the second resin RS2 may include the second base resin BS2, and the heat radiating material HCP, the light blocking material, and the foaming agent that are each dispersed in the second base resin BS2. However, without being limited thereto, the second resin RS2 may further include an additional additive such as an electromagnetic shielding material.

Referring to FIGS. 8, 9C, and 9D, the curing the second resin RS2 may form the second protective part PL2 by providing heat to the second resin RS2. The second resin RS2 may be cured by providing the heat to the second resin RS2 provided on the lower surface DP-LF of the display panel DP. As the second resin RS2 includes the thermosetting resin, the second resin RS2 may be cured by the heat to form the second protective part PL2 from a second cured portion PL2-P. Here, outer side surfaces of the first protective part PL1 face inner side surfaces of the second protective part PL2. A side surface of the first protective part PL1 and a side surface of the second protective part PL2 contact each other. The interface of the first and second protective parts PL1 and PL2 may correspond to a boundary between the second region PA and the third region NSA.

Referring to FIGS. 8 and 9E, the method of manufacturing the electronic device ED includes providing the electronic module EM (S400). The electronic module EM may be defined to overlap the first region SA of the display panel DP. As the hole HH of the protective layer PL overlaps the first region SA, the electronic module EM may operate without deterioration in optical characteristics even though the electronic module EM is disposed to overlap the first region SA.

As the electronic device ED according to an embodiment of the present disclosure includes, under the display panel DP, the protective layer PL that performs multiple functions, effects of reducing the thickness of the electronic device ED and simplifying parts may be obtained. As the display panel DP includes light emitting elements, various side effects may occur. To compensate for the side effects, an electronic device ED in the related art includes, under the display panel DP, a plurality of members or layers along a thickness direction such as an electromagnetic or light shielding layer, a heat radiating layer, a cushion layer, and a support layer. In contrast, in the present disclosure, a single layer of the protective layer PL that performs the multiple functions discussed above is disposed under the display panel DP. Accordingly, the protective layer PL may perform the functions performed by the plurality of layers in the related art, and thickness reduction, part simplification, and an increase in manufacturing process efficiency may be achieved. As the protective layer PL is disposed under the display panel DP in the electronic device ED according to an embodiment of the present disclosure, the impact resistance of the display panel DP against an external impact may be increased.

In the case of the electronic device according to an embodiment of the present disclosure, the protective layer PL may include the first protective part PL1 overlapping the second region PA and the second protective part PL2 overlapping the third region NSA, and thus the process reliability of the electronic device ED may be improved. The first protective part PL1 of the protective layer PL that overlaps the second region PA adjacent to the first region SA may be provided through a process separate from that of the second protective part PL2. For example, the first protective part PL1 may be formed before the formation of the second protective part PL2 and may be formed to correspond to the local second region PA through an ink-jet process or a process such as dispensing. Accordingly, a defect rate of the electronic device ED may be reduced. In addition, as the second protective part PL2 overlapping the third region NSA occupying most of the active region AA of the display panel DP includes the heat radiating material HCP, the protective layer PL may effectively release heat generated from the display panel DP, and thus the reliability of the electronic device ED may be improved. As the first protective part PL1 does not include a heat radiating material HCP, the material for providing the first protective part PL1 may be uniformly applied to the second region PA corresponding to a local region of the display panel DP in the process of forming the protective layer PL, and a nozzle clogging phenomenon may be prevented. Thus, the process reliability of the electronic device ED may be improved.

The method of manufacturing the electronic device ED may further include forming the third protective part PL3. FIGS. 10A to 10E are schematic cross-sectional views illustrating the forming the third protective part PL3 and the forming the second protective part PL2 in the method of manufacturing the electronic device ED. In FIGS. 10A to 10E, structures corresponding to FIG. 5B described above are schematically illustrated.

Referring to FIGS. 10A and 10B, a third resin RS3 may be applied to the lower surface DP-LF of the display panel DP through a third nozzle NZ3. The third resin RS3 may be provided to a portion corresponding to the peripheral region NAA in the display panel DP. The third resin RS3 may be provided to an entirety of the peripheral region NAA. In an embodiment, the third resin RS3 may be directly applied to the lower surface DP-LF of the display panel DP at the peripheral region NAA thereof. Accordingly, a separate adhesive layer is not required between the display panel DP and the third protective part PL3, and thus the process reliability of the electronic device ED may be improved.

To implement a planar shape in which the third protective part PL3 is specifically formed only in the peripheral region NAA, the forming the third protective part PL3 may be performed through a specific process. Applying the third resin RS3 may be performed through, for example, an ink-jet process or a process such as dispensing. As the applying the third resin RS3 is performed through the ink-jet process or the dispensing process, the third resin RS3 may be uniformly applied to correspond to the local peripheral region NAA. Accordingly, the process reliability of the electronic device ED may be improved.

The third resin RS3 may include a UV curable resin. The third resin RS3 may include the same material as the first resin RS1 described above. The description of the material included in the above-described first resin RS1 may be identically applied to the material included in the third resin RS3.

The third resin RS3 does not include a heat radiating material HCP. Since the third resin RS3 is applied to the peripheral region NAA, which corresponds to a portion that is relatively local when compared to the third region NSA in the display panel DP, to have a specific planar shape, a process such as ink-jet printing or dispensing may be used. When the third resin RS3 includes a heat radiating material HCP, problems such as a nozzle clogging phenomenon and a heterogeneous surface may occur due to the heat radiating material HCP. However, in the present disclosure, the third resin RS3 for forming the third protective part PL3 does not include a heat radiating material HCP (e.g., excludes the heat radiating material HCP). Accordingly, the coating reliability of the third resin RS3 may be improved, the nozzle clogging phenomenon may be prevented, and a uniform thin film may be formed. Thus, the process reliability of the electronic device ED may be improved.

Referring to FIGS. 10B and 10C, curing the third resin RS3 may form a third cured portion PL3-P by providing light UV to the third resin RS3. The third resin RS3 may be cured by providing the light UV to the third resin RS3 provided on the lower surface DP-LF of the display panel DP. The light UV may be UV light. For example, the light UV may be UV light having a central wavelength in a wavelength range of about 100 nm to about 400 nm. The third resin RS3 may be photo-cured by the UV light UV. As the third resin RS3 includes the UV curable resin, the third resin RS3 may be cured by the UV light to form the third protective part PL3 from the third cured portion PL3-P.

Referring to FIGS. 10C and 10D, the second resin RS2 for forming the second protective part PL2 may be applied after the forming the third protective part PL3. Referring to FIG. 10C, the second resin RS2 may be applied to the lower surface DP-LF of the display panel DP through the second nozzle NZ2. The second resin RS2 may be provided to a portion corresponding to the third region NSA in the display panel DP. In an embodiment, the second resin RS2 may be directly applied to the lower surface DP-LF of the display panel DP. Accordingly, a separate adhesive layer is not required between the display panel DP and the second protective part PL2, and thus the process reliability of the electronic device ED may be improved.

The forming the second protective part PL2 may be performed by various methods. The forming the second protective part PL2 may be performed by at least one of spin coating, slit coating, jet printing, metal mask printing and screen printing. For example, the forming the second protective part PL2 may be performed by screen printing.

In an embodiment, the second protective part PL2 and the third protective part PL3 may be formed through different processes. In an embodiment, the process of applying the third resin RS3 may be performed through an ink-jet process or a dispensing process, and the process of applying the second resin RS2 may be performed by screen printing.

The second resin RS2 may include a heat radiating material HCP. The second resin RS2 may include the second base resin BS2 and the heat radiating material HCP which is dispersed in the second base resin BS2. The second base resin BS2 may include at least one of an acrylate-based resin, a urethane-based resin, a fluorine-based resin, an epoxy-based resin, a polyester-based resin, a polyamide-based resin and a silicone-based resin. The second base resin BS2 may be an acrylate-based resin, a urethane-based resin, a fluorine-based resin, an epoxy-based resin, a polyester-based resin, a polyamide-based resin, or a silicone-based resin provided in the form of a monomer or an oligomer. The second base resin BS2 included in the second resin RS2 may be in a liquid form before curing and may include a thermosetting resin.

In an embodiment, the second resin RS2 may further include at least one of a light blocking material and a foaming agent, in addition to the heat radiating material HCP. For example, the second resin RS2 may include the second base resin BS2, and the heat radiating material HCP, the light blocking material, and the foaming agent that are each dispersed in the second base resin BS2. However, without being limited thereto, the second resin RS2 may further include an additional additive such as an electromagnetic shielding material.

Referring to FIGS. 10D and 10E, curing the second resin RS2 may form the second cured portion PL2-P by providing heat to the second resin RS2. The second resin RS2 may be cured by providing the heat to the second resin RS2 provided on the lower surface DP-LF of the display panel DP. As the second resin RS2 includes the thermosetting resin, the second resin RS2 may be cured by the heat to form the second protective part PL2 from the second cured portion PL2-P.

According to one or more embodiment of the present disclosure, in the protective layer PL facing the display panel DP in the electronic device ED, the protective layer portion closest to the transmission region where the electronic module EM is disposed and other protective layer portion include different materials from each other. Accordingly, the protective layer portion closest to the sensing region may be easily formed in a shape or area corresponding to the local sensing region of the display panel DP, and heat generated from the display panel DP may be effectively released. Thus, the reliability of the electronic device ED may be improved.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An electronic device comprising:
a display panel including a first region corresponding to an electronic module, a second region which extends from the first region, and a third region which is spaced apart from the first region with the second region therebetween; and
a protective layer facing the display panel at the second region and the third region, the protective layer including:
a first protective part including an ultraviolet curable resin, the first protective part being adjacent to the first region and overlapping the second region; and
a second protective part including a heat radiating material, the second protective part being adjacent to the second region and overlapping the third region.

2. The electronic device of claim 1, wherein at least one of the first protective part and the second protective part further includes a light blocking material.

3. The electronic device of claim 1, wherein the first protective part includes a light blocking material including an ultraviolet transmitting material.

4. The electronic device of claim 1, wherein at least one of the first protective part and the second protective part further includes a foaming agent.

5. The electronic device of claim 1, wherein
the second protective part further includes a thermosetting resin, a light blocking material, a foaming agent and an additive, and
the additive includes a thermal initiator or an electromagnetic shielding material.

6. The electronic device of claim 1, wherein
the protective layer defines a hole therein which overlaps the first region, and
the first protective part of the protective layer surrounds the hole.

7. The electronic device of claim 1, wherein
the display panel includes a lower surface closest to the protective layer, and
the protective layer is directly on the lower surface of the display panel.

8. The electronic device of claim 1, wherein a thickness of the first protective part and a thickness of the second protective part range from about 50 micrometers to about 300 micrometers.

9. The electronic device of claim 1, wherein the first protective part has substantially the same thickness as the second protective part.

10. The electronic device of claim 1, wherein the first protective part and the second protective part are coplanar with each other.

11. The electronic device of claim 1, wherein the protective layer further includes a filling layer which is coplanar with the first protective part and the second protective part, overlaps the first region and transmits light.

12. The electronic device of claim 1, wherein the heat radiating material of the second protective part adjacent to the second region and overlapping the third region has an average diameter of about 5 micrometers to about 100 micrometers.

13. The electronic device of claim 1, wherein
the display panel further includes:
an active region including the first region, the second region and the third region; and
a peripheral region adjacent to the active region, and
the protective layer overlaps the peripheral region.

14. The electronic device of claim 13, wherein the protective layer further includes a third protective part including an ultraviolet curable resin, the third protective part being coplanar with the first protective part and the second protective part, adjacent to the third region and overlapping the peripheral region.

15. An electronic device comprising:
a display panel including a first region corresponding to an electronic module, a second region which extends from the first region, and a third region which is spaced apart from the first region with the second region therebetween; and
a protective layer facing the display panel at the second region and the third region, the protective layer including:
a first protective part including a first base resin and an ultraviolet curable resin, the first protective part being adjacent to the first region and overlapping the second region; and
a second protective part including a second base resin different from the first base resin and a heat radiating material which is in the second base resin, the second protective part being coplanar with the first protective part, adjacent to the second region and overlapping the third region.

16. A method of providing an electronic device, the method comprising:
providing a display panel including a first region corresponding to an electronic module, a second region which extends from the first region, and a third region which is spaced apart from the first region with the second region therebetween;
providing a first protective part of a protective layer on a lower surface of the display panel, by providing a first resin having an ultraviolet curable resin, to the lower surface of the display panel at the second region thereof;
providing a second protective part of the protective layer, by providing a second resin having a heat radiating material, to the lower surface of the display panel at the third region thereof; and
providing the electronic module facing the first region of the display panel.

17. The method of claim 16, wherein the providing of the first protective part includes curing the first resin which is on the lower surface of the display panel at the second region thereof, using ultraviolet light.

18. The method of claim 16, wherein the providing of the second protective part includes:
after the providing of the first protective part on the lower surface of the display panel, applying the second resin to the lower surface of the display panel at the third region thereof; and
curing the second resin which is on the lower surface of the display panel at the third region thereof, using heat.

19. The method of claim 16, wherein
the second resin further includes a thermosetting resin, a light blocking material, a foaming agent, and an additive, and
the additive includes a thermal initiator or an electromagnetic shielding material.

20. The method of claim 16, wherein the display panel further includes an active region including the first region, the second region and the third region, and a peripheral region which is adjacent to the active region,
further comprising, before the providing of the second protective part, providing a third protective part of the protective layer, by providing a third resin having the ultraviolet curable resin, to the lower surface of the display panel at the peripheral region thereof.
